(19) United States
(12) Patent Application Publication
(10) Pub. No.: US 2006/0067062 A1
(43) Pub. Date: Mar. 30, 2006

(54) Electronic apparatus incorporating printed circuit board with grounding land

(75) Inventors: Toshio Ishimoto, Takefu-city (JP); Naofumi Okayama, Takefu-city (JP); Toshihiko Sasaki, Takefu-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Takefu-city (JP)

(21) Appl. No.: 11/226,305

(22) Filed: Sep. 15, 2005

(30) Foreign Application Priority Data
Sep. 27, 2004 (JP) 2004-279326

(51) Int. Cl. H05K 7/04; H05K 7/06

(52) U.S. Cl. 361/753; 174/255; 361/777

(57) ABSTRACT

To provide a grounding structure for connecting and fixing a printed circuit board and a conductive frame to a conductive chassis of an electronic apparatus, the height of solder applied to the grounding land is made uniform, thereby ensuring electrical connection between the printed circuit board and the conductive chassis. A copper-foil coating 54 formed on a printed circuit board 50 is divided by a substantially-lattice-shaped resist 55 to form a grounding land 56 including a plurality of obliquely elongated land elements 56c in an area close to the edge of an opening 51 and a plurality of rhombic land elements 56a in the remaining area, and the grounding land 56 is brought into contact with and screw-clamped to a conductive chassis 60 using a locking leg 41.

The present application is based on and claims priority of Japanese patent application No. 2004-279326 filed on Sep. 27, 2004, the entire contents of which are hereby incorporated by reference.

### BACKGROUND OF THE INVENTION

1. Field of the Invention

The present invention relates to a grounding structure that connects a printed circuit board to a conductive chassis of an electronic apparatus for grounding and electrically connects a conductive frame holding an electronic device or component in the electronic apparatus to the conductive chassis. In particular, it relates to an electronic apparatus incorporating a printed circuit board having a grounding land, in which the grounding land formed on the printed circuit board is divided by a resist into a plurality of land elements so as to ensure that, when solder is applied to the land elements, the solders on the land elements are uniform in height and contact area, thereby ensuring reliable electrical connection between the solders on the grounding land elements and a conductive chassis, and improving the ease of assembly of the printed circuit board and the conductive frame onto the conductive chassis.

2. Description of the Related Art

According to a conventional technique for grounding a printed circuit board, solder is applied to a patterned-copper-foil land on the printed circuit board, and the land is brought into intimate contact with a housing frame by screw clamping or the like. FIGS. 6 to 8 show an exemplary conventional technique. FIG. 6(a) shows a conductive frame 40 that supports an electronic device (not shown). The conductive frame 40 has a locking leg 41 to be fixed to a conductive chassis 60 with a screw, and the conductive frame 40 and the a printed circuit board 50 can be connected to the conductive chassis 60 for grounding by holding the printed circuit board 50 between the locking leg 41 and the conductive chassis 60. The conductive chassis 60 shown in FIG. 6(c) has a supporting mount 61, which is brought into direct contact with a grounding land 56 on the printed circuit board 50 (FIG. 6(b)) and is brought into contact with a chassis contacting part 42b of the locking leg 41 of the conductive frame 40 and screw-clamped to the chassis contacting part 42b. In addition, the printed circuit board 50 has a substantially rectangular opening 51 for accommodating the chassis contacting part 42b of the conductive frame 40. Board pressing parts 42a of the conductive frame 40 are brought into contact with a component mounting surface 50a of the printed circuit board 50 at the opposite sides of the opening 51, and the grounding land 56 of the printed circuit board 50, which is brought into contact with the supporting mount 61 on the conductive chassis 60, is formed on a patterned surface 50b of the printed circuit board 50, which is opposite to the component mounting surface 50a. Furthermore, the chassis contacting part 42b and the board pressing parts 42a of the locking leg 41 of the conductive frame 40 are formed to be different in height by approximately the thickness of the printed circuit board 50. The chassis contacting part 42b and the supporting mount 61 can be clamped to each other using a screw through a screw hole 42c in the chassis contacting part 42b and a screw hole 61c in the supporting mount 61, thereby fixedly connecting the conductive frame 40 and the printed circuit board 50 to the conductive chassis 60 and connecting for grounding.

Now, with reference to FIG. 7, the shape of the grounding land 56 formed on the patterned surface 50b of the printed circuit board 50 and the substantially rectangular opening 51 will be described. The opening 51 has a size enough to accommodate the chassis contacting part 42b of the locking leg 41 of the conductive frame 40 shown in FIG. 6, and a copper-foil coating 54 is spaced apart from an opening edge 52 by approximately 0.5 mm. In the case where the opening 51 is relatively large and is formed using a press die (not shown), the copper-foil coating may be torn off when pulling the die off. The space is intended to avoid such a problem. In addition, in this drawing, a pair of substantially semicircular grounding lands 56 are shown above and below the opening 51, and the grounding lands 56 are geometrically similar to board contacting parts 61a of the supporting mount 61 on the conductive chassis 60.

The arrow shown in FIG. 7 indicates the direction of movement of the printed circuit board with respect to molten solder in the case where flow soldering is performed. As can be seen from FIG. 7, copper-foil coatings 54 are spaced apart from the edge 52 of the opening 51 in the printed circuit board 50 by approximately 0.5 mm, and solder 90 is applied to the copper-foil coatings 54, which are not coated with a resist 55, to a substantially uniform thickness. Although not shown, the amount of solder on the printed circuit board is smaller in forward areas and greater in rearward areas along the direction of movement of the printed circuit board indicated by the arrow. Thus, the height of the applied solder varies from place to place depending on the direction of movement of the printed circuit board. According to a technique to solve this problem, as shown in FIG. 8, taking into account the general behavior of solder, the substantially semicircular grounding land 56 shown in FIG. 7 is coated with a network of resist 55, thereby dividing the grounding land 56 into a plurality of rhombic lands 56a, and flow soldering is performed as in the case shown in FIG. 7. Such division improves the variation of the amount of solder depending on the direction of movement of the printed circuit during flow soldering. However, lands close to the opening edge 52 are triangular, rather than rhombic, because of the 0.5-mm space that is not coated with copper foil. The triangular lands 56b, which have a smaller area, cannot hold a sufficient amount of solder, so that the height of the applied solder is reduced. Thus, the amount of solder varies between the rhombic lands 56a and the triangular lands 56b.

As a prior-art technique for forming a grounding land of a printed circuit board, Japanese Patent Publication No. 2003-309333 discloses a method for forming a grounding land of a printed circuit board. According to this method, at the area where a copper-foil pattern on a printed circuit board is in contact with a board mounting screw, the copper foil is exposed in a pattern of parallel narrow stripes in the vicinity of a screw hole for the board mounting screw. The gaps between the stripes of copper foil are not coated with a resist. As a result, there is formed a grounding land composed of a plurality of parallel narrow stripes of copper foil on the base material of the printed circuit board. Solder is applied to the copper foil pattern by flow soldering or the like to form a solder pad, and the screw head is in contact with the solder pad to provide electrical conduction.

As described above, according to the prior-art technique, there is a problem with product quality that, when a press die is used to shape a printed circuit board or to form an opening, which serves as a component insertion hole, in the printed circuit board, a copper-foil coating may be torn off by the cutting blade of the die if the opening is relatively large or that solder may adhere to a protruding part of the torn copper-foil coating, and a piece of copper foil or a piece of solder may drop later. In order to solve this problem, it is common practice to form the copper-foil coating slightly spaced apart from the edge of the opening in the printed circuit board. Furthermore, there is a possibility that the copper-foil coating easily peels off by heat during soldering, if the periphery of the copper-foil coating is not coated with a resist, and an edge or corner thereof is exposed. In order to avoid the possibility, the grounding land formed around the opening is made from one copper-foil coating, and a resist is applied to the surface of the copper-foil coating in such a manner that the copper-foil coating has a plurality of rhombic exposed areas. However, in this case, there is a problem that a plurality of exposed areas, which would otherwise be rhombic exposed areas, are triangular exposed areas because of the presence of the opening, and thus, those exposed areas have a reduced area.

### SUMMARY OF THE INVENTION

According to a first implementation of the present invention, there is provided an electronic apparatus incorporating a printed circuit board having a grounding land, an electronic component being mounted on the printed circuit board, in which an opening is formed through the printed circuit board, a copper-foil coating for grounding is formed on the printed circuit board at a predetermined distance from an edge of the opening, the copper-foil coating is divided by a lattice-shaped resist into a plurality of land elements, and the plurality of land elements are formed in such a manner that land elements close to the edge of the opening have an area equal to or larger than the area of land elements away from the edge of the opening. Furthermore, the present invention provides a grounding method, according to which: the triangular land elements formed in the vicinity of the opening are integrated with their respective obliquely adjacent rhombic land elements to form obliquely elongated land elements, thereby providing an adequate area of exposed copper-foil coating and ensuring that an adequate amount of solder is applied to each land element; the obliquely elongated land elements are disposed in such a manner that, during flow soldering, as the printed circuit board moves, the molten solder is drawn toward the opening by the action of the interfacial tension between the molten solder and the copper-foil coating, and the height of the solder applied to the narrow corner of the obliquely elongated land element increases, thereby adjusting the heights of solder on the rhombic land elements, the obliquely elongated land elements and the land elements located along the periphery of the grounding land, thereby ensuring the contact between the grounding land on the printed circuit board and the conductive chassis; the grounding land is in direct contact with the conductive chassis and thus is electrically connected thereto with reliability; and the printed circuit board, which is screw-clamped to the conductive chassis, is pressed against the conductive chassis by the locking leg of the conductive frame, and thus, the resiliency of the stepped parts of the locking leg prevents loosening of the screw due to a creep of the solder.

According to the arrangement of the first implementation, in an electronic apparatus incorporating a printed circuit board having a grounding land, an electronic component being mounted on the printed circuit board, an opening is formed through the printed circuit board, a copper-foil coating for grounding is formed on the printed circuit board at a predetermined distance from an edge of the opening, the copper-foil coating is divided by a lattice-shaped resist into a plurality of land elements, and the plurality of land elements are formed in such a manner that land elements close to the edge of the opening have an area equal to or larger than the area of land elements away from the edge of the opening. Thus, once the printed circuit board is soldered, reliable and stable grounding can be achieved, since the plurality of land elements are formed in such a manner that land elements close to the edge of the opening have an area equal to or larger than the area of land elements away from the edge of the opening.

According to a second implementation of the present invention, there is provided an electronic apparatus incorporating a printed circuit board having a grounding land, comprising: a conductive frame for holding an electronic device or component incorporated therein; a printed circuit board on which the electronic component is mounted; and a conductive chassis to which the conductive frame and the printed circuit board are fixed by screw clamping to provide electrical grounding, the conductive chassis having a raised supporting mount which supports the printed circuit board and serves as a contact surface for grounding, the conductive frame having a locking leg having stepped parts which are different in height by approximately the thickness of the printed circuit board, one of the stepped parts serving to pressing the printed circuit board against the supporting mount, and the other of the stepped parts passing through an opening formed in the printed circuit board and being screw-clamped to the supporting mount, in which a copper-foil coating for grounding is formed on the printed circuit board at a predetermined distance from an edge of the opening, the copper-foil coating is divided by a lattice-shaped resist into a plurality of rhombic land elements, each of which has a substantially rhombic shape, and a plurality of obliquely elongated land elements are disposed along the edge of the opening.

According to the arrangement of the second implementation, in an electronic apparatus, comprising: a conductive frame for holding an electronic device or component incorporated therein; a printed circuit board on which the electronic component is mounted; and a conductive chassis to which the conductive frame and the printed circuit board are fixed by screw clamping to provide electrical grounding, the conductive chassis having a raised supporting mount which supports the printed circuit board and serves as a contact surface for grounding, the conductive frame having a locking leg having stepped parts which are different in height by approximately the thickness of the printed circuit board, one of the stepped parts serving to pressing the printed circuit board against the supporting mount, and the other of the stepped parts passing through an opening formed in the printed circuit board and being screw-clamped to the supporting mount, a copper-foil coating for grounding is formed on the printed circuit board at a predetermined distance from an edge of the opening, the copper-foil coating is divided by a lattice-shaped resist into a plurality of rhombic land elements, each of which has a substantially rhombic shape, and a plurality of obliquely elongated land elements are disposed along the edge of the opening. Thus, the printed circuit board can be in direct contact with the supporting mount on the conductive chassis for grounding, and the locking leg, which passes through the opening in the printed circuit board, can be in direct contact with the supporting mount for grounding. In addition, the locking leg has a stepped part presses the printed circuit board against the supporting mount. By a simple assembly process, that is, by simply screw-clamping the locking leg to the conductive chassis, the printed circuit board and the conductive frame can be readily brought into contact with and firmly pressed against the conductive chassis, so that grounding thereof can be achieved with reliability. Furthermore, the printed circuit board has a copper-foil coating to be connected to the conductive chassis for grounding, and the copper-foil coating is divided by a resist into a plurality of obliquely elongated land elements in the vicinity of the opening and a plurality of rhombic land elements surrounding the obliquely elongated land elements. Thus, when soldering the printed circuit board, the amounts of solder on the obliquely elongated land elements and the rhombic land elements can be adjusted, and the copper-foil coating for grounding can be in direct surface contact with the supporting mount on the conductive chassis, so that reliable and stable grounding can be achieved.

According to a third implementation of the present invention, in the electronic apparatus incorporating a printed circuit board having a grounding land according to the first or second implementation, the plurality of obliquely elongated land elements abutting on the edge of the opening are disposed so as to extend outward from the opening in a direction in which the printed circuit board moves while being in contact with molten solder during flow soldering.

According to the arrangement of the third implementation, the plurality of obliquely elongated land elements abutting on the edge of the opening are disposed so as to extend outward from the opening in a direction in which the printed circuit board moves while being in contact with molten solder during flow soldering. The obliquely elongated land element has an acute-angled corner on the side of the opening, and the amount of solder on the acute-angled corner tends to decrease. However, since the obliquely elongated land element is disposed so as to extend outward from the opening along the direction of movement of the printed circuit board during flow soldering, or in other words, the obliquely elongated land element is disposed so as to extend toward the opening along the direction opposite to the movement direction of the printed circuit board during flow soldering, the obliquely elongated land element comes into contact with the molten solder, first at the end thereof away from the opening and last at the end thereof close to the opening, as the printed circuit board moves. As a result, the solder to adhere to the obliquely elongated land element is drawn toward the opening by the action of the interfacial tension of the molten solder, and the amount of solder adhering to the acute-angled corner of the obliquely elongated land element close to the opening can be increased. Thus, solder can be applied to the obliquely elongated land element uniformly over the whole surface thereof.

According to a fourth implementation of the present invention, in the electronic apparatus incorporating a printed circuit board having a grounding land according to the first implementation, the copper-foil coating for grounding is formed on the printed circuit board at a predetermined distance from the edge of the opening, the copper-foil coating is divided by a lattice-shaped resist into a plurality of substantially rhombic land elements, and the copper-foil coating is expanded toward the edge of the opening to form a plurality of rhombic land elements along the edge of the opening.

According to the arrangement of the fourth implementation, the copper-foil coating for grounding is formed on the printed circuit board at a predetermined distance from the edge of the opening, the copper-foil coating is divided by a lattice-shaped resist into a plurality of substantially rhombic land elements, and the copper-foil coating is expanded toward the edge of the opening to form a plurality of rhombic land elements along the edge of the opening. Since there are provided a plurality of rhombic land elements abutting on the edge of the opening without any predetermined distance from the edge of the opening, the amount of solder applied to the grounding land composed of rhombic land elements can be uniform, the grounding land can be in direct surface contact with the supporting mount on the conductive chassis, and thus, reliable and stable grounding can be achieved.

According to the first implementation of the present invention, in an electronic apparatus incorporating a printed circuit board having a grounding land, an electronic component being mounted on the printed circuit board, an opening is formed through the printed circuit board, a copper-foil coating for grounding is formed on the printed circuit board at a predetermined distance from an edge of the opening, the copper-foil coating is divided by a lattice-shaped resist into a plurality of land elements, and the plurality of land elements are formed in such a manner that land elements close to the edge of the opening have an area equal to or larger than the area of land elements away from the edge of the opening. Thus, the amount of solder applied to the land elements close to the edge of the opening can be at least equal to the amount of solder applied to the land elements away from the edge of the opening, and thus, reliable and stable grounding can be achieved.

According to the second implementation of the present invention, in an electronic apparatus, comprising: a conductive frame for holding an electronic device or component incorporated therein; a printed circuit board on which the electronic component is mounted; and a conductive chassis to which the conductive frame and the printed circuit board are fixed by screw clamping to provide electrical grounding, the conductive chassis having a raised supporting mount which supports the printed circuit board and serves as a contact surface for grounding, the conductive frame having a locking leg having stepped parts which are different in height by approximately the thickness of the printed circuit board, one of the stepped parts serving to pressing the printed circuit board against the supporting mount, and the other of the stepped parts passing through an opening formed in the printed circuit board and being screw-clamped to the supporting mount, a copper-foil coating for grounding is formed on the printed circuit board at a predetermined distance from an edge of the opening, the copper-foil coating is divided by a lattice-shaped resist into a plurality of rhombic land elements, each of which has a substantially rhombic shape, and a plurality of obliquely elongated land elements are disposed along the edge of the opening. According to a prior-art technique, triangular land elements are formed close to the opening, and the triangular land elements generally have an area about one-half of that of rhombic land elements and have acute-angled corners, so that highly viscous molten solder is hard to adhere to the triangular land elements. However, according to the present invention, the triangular land elements are integrated with rhombic land elements obliquely adjacent at the opposite side of the opening, thereby forming obliquely elongated land elements, which have a larger area than the triangular land elements and have a reduced number of acute-angled corners compared with the triangular land elements. Thus, application of solder to the land elements can be improved, and the grounding land is in direct surface contact with the supporting mount on the conductive chassis, so that reliable and stable grounding can be achieved. Furthermore, since the obliquely elongated land elements and the rhombic land elements are constituted by one copper-foil coating divided by a substantially-lattice-shaped resist, it is possible to avoid a problem that, if a plurality of land elements are made from a plurality of copper-foil coatings, the outer peripheries of the copper-foil coatings are easy to peel off when heated for soldering.

According to the third implementation of the present invention, the plurality of obliquely elongated land elements abutting on the edge of the opening are disposed so as to extend outward from the opening in a direction in which the printed circuit board moves while being in contact with molten solder during flow soldering. The obliquely elongated land element has an acute-angled corner on the side of the opening, and the amount of solder on the acute-angled corner tends to decrease. However, since the obliquely elongated land element is disposed so as to extend outward from the opening along the direction of movement of the printed circuit board during flow soldering, or in other words, the obliquely elongated land element is disposed so as to extend toward the opening along the direction opposite to the movement direction of the printed circuit board during flow soldering, the obliquely elongated land element comes into contact with the molten solder, first at the end thereof away from the opening and last at the end thereof close to the opening, as the printed circuit board moves. As a result, the solder to adhere to the obliquely elongated land element is drawn toward the opening by the action of the interfacial tension of the molten solder, and the amount of solder adhering to the acute-angled corner of the obliquely elongated land element close to the opening can be increased. Thus, solder can be applied to the obliquely elongated land element uniformly over the whole surface thereof. As a result, the contact area between the grounding land and the supporting mount on the conductive chassis can be increased compared with the prior-art grounding land including triangular land elements.

According to the fourth implementation of the present invention, the copper-foil coating for grounding is formed on the printed circuit board at a predetermined distance from the edge of the opening, the copper-foil coating is divided by a lattice-shaped resist into a plurality of substantially rhombic land elements, and the copper-foil coating is expanded toward the edge of the opening to form a plurality of rhombic land elements along the edge of the opening. Since there are provided a plurality of rhombic land elements abutting on the edge of the opening without any predetermined distance from the edge of the opening, the amount of solder applied to the grounding land composed of rhombic land elements can be uniform, the grounding land can be in direct surface contact with the supporting mount on the conductive chassis, and thus, reliable and stable grounding can be achieved. In addition, since the triangular land elements are expanded close to the edge of the opening to form rhombic land elements, the possibility that the copper-foil coating is torn off when forming the opening using a die during fabrication of the printed circuit board can be reduced to a minimum. Furthermore, since the amount of the copper-foil coating torn off is reduced to a minimum, it is possible to reduce to a minimum the possibility that, after the printed circuit board is soldered, the solder adhering to the copper-foil coating drops and causes performance degradation of the electronic apparatus.

### BRIEF DESCRIPTION OF THE DRAWINGS

FIG. 1 is a schematic diagram showing a configuration of a grounding land according to a first embodiment of the present invention;

FIG. 2 is a diagram for illustrating a soldered printed circuit board on which rhombic land elements and obliquely elongated land elements are formed according to the first embodiment of the present invention;

FIG. 3 is a cross-sectional view of the printed circuit board on which rhombic land elements and obliquely elongated land elements are formed according to the present invention;

FIG. 4 is a diagram for illustrating soldered rhombic land elements according to a second embodiment of the present invention;

FIG. 5 is a schematic cross-sectional view of an assembly of a conductive chassis, a printed circuit board and a conductive frame according to the present invention, in which a grounding land on the printed circuit board is in contact with the conductive chassis, sandwiched between the conductive chassis and the conductive frame and screw-clamped to the conductive chassis;

FIG. 6 shows an assembly procedure according to a prior-art technique, in which a grounding land on a printed circuit board is brought into contact with a conductive chassis, sandwiched between the conductive chassis and a conductive frame and then screw-clamped to the conductive chassis;

FIG. 7 is a diagram for illustrating a conventional grounding land; and

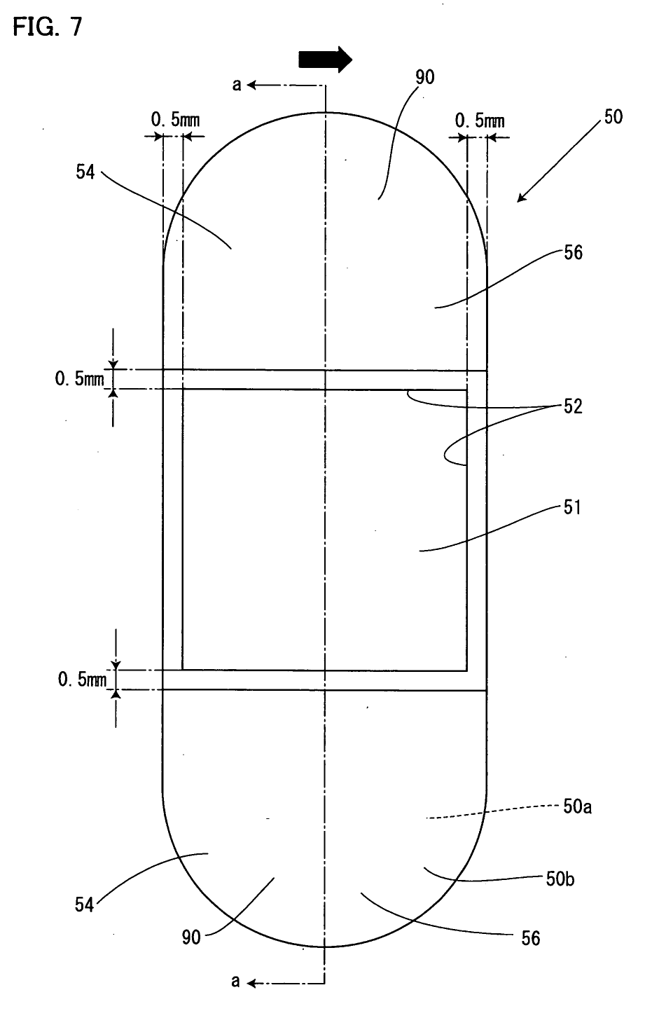

FIG. 8 is a diagram showing a conventional grounding land comprising rhombic land elements and triangular land elements.

### DETAILED DESCRIPTION OF THE PREFERRED EMBODIMENTS

As described above, according to the present invention, a grounding land, which is to be brought into contact with a conductor for grounding, is constituted by a large copper-foil coating, the grounding land is divided by a resist into a plurality of land elements, and the shape of land elements that cannot hold a sufficient amount of solder is modified to eliminate variations in the amount of solder among the land elements, thereby ensuring desired stable grounding. In the following description of embodiments of the present invention, with regard to a printed circuit board having an opening for accommodating a part of a locking leg of a conductive frame that supports an electronic device or component, optimal configurations of a grounding land formed in the vicinity of the opening in the printed circuit board will be described.

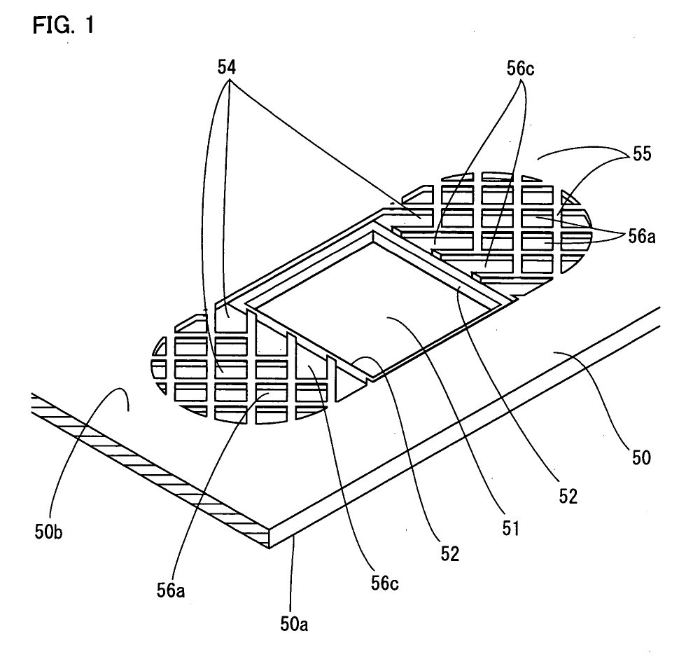

In the following, as the best modes for carrying out the present invention, embodiments of the present invention will be described with reference to FIGS. 1 to 5. However, of course, the embodiments of the present invention described herein can be readily modified without departing from the spirit of the present invention.

### First Embodiment

FIGS. 1 to 3 are schematic diagrams for illustrating a configuration of obliquely elongated land elements according to a first embodiment of the present invention.

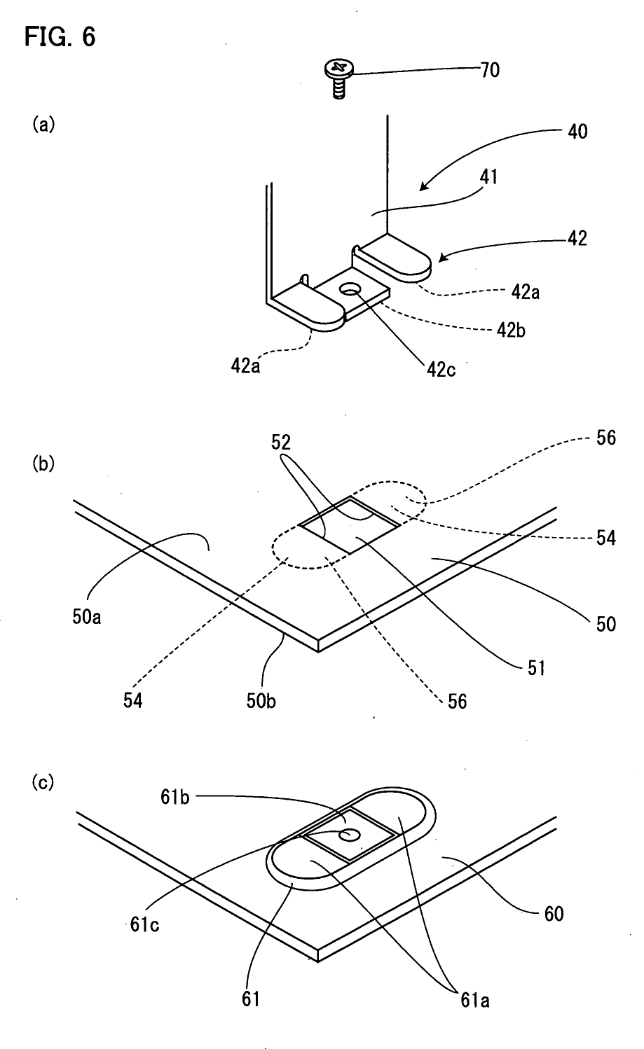

FIG. 1 shows a printed circuit board 50 to which the present invention is applied. The printed circuit board 50 has a substantially rectangular opening 51 for accommodating a chassis contacting part 42b of a stepped section 42 of a locking leg 41 of a conductive frame 40 that supports an electronic device or component (not shown) described above with regard to the prior-art technique and shown in FIG. 6(a). A copper-foil coating 54 is formed surrounding the opening 51. The copper-foil coating 54 is previously spaced apart from the opening 51 by 0.5 mm in order to prevent the copper-foil coating from being torn off when forming the opening 51 with a die (not shown) during fabrication of the printed circuit board. The copper-foil coating 54 is in contact with a raised supporting mount formed on a conductive chassis 60 shown in FIG. 6(c) and described with regard to the prior-art technique. A component mounting surface 50a of the printed circuit board 50, which is opposite to the surface on which the copper-foil coating 54 is formed, is a surface against which a board pressing part 42a of the locking leg 41 of the conductive frame 40 is to be pressed, and on the component mounting surface 50a, two substantially semicircular grounding lands 56 are oppositely disposed with the opening 51 interposed therebetween. The peripheries of the grounding lands are coated with a resist 55 to prevent solder from adhering thereto.

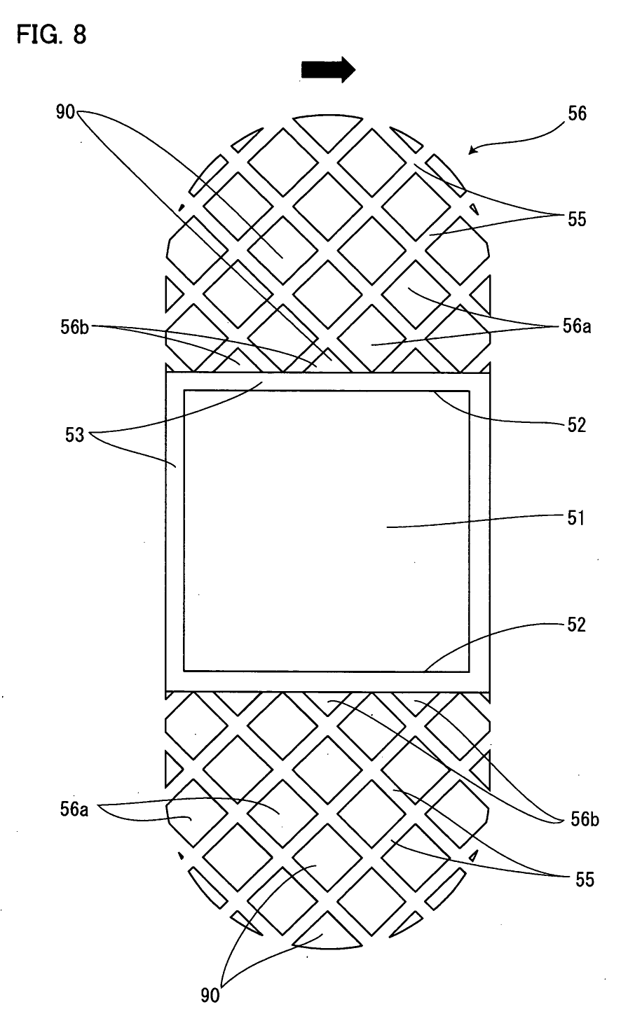

In the prior-art technique shown in FIG. 8, a plurality of triangular land elements 56b are formed along the edge of the opening 51, and a plurality of rhombic land elements 56a are formed away from the opening 51. In contrast, according to this embodiment, triangular land elements 56a formed along the edge of the opening are connected to their respective obliquely adjacent rhombic land elements 56a to form obliquely elongated land elements 56c, and thus, the grounding lands 56 comprises a plurality of obliquely elongated land elements 56c, which are separated from each other by the lattice-shaped resist 55. Thus, the grounding lands 56 shown in FIG. 1 each have a plurality of obliquely elongated land elements 56c, which have a larger area, along the side close to the opening 51 and a plurality of rhombic land elements 56a in the area away from the opening 51.

By changing the triangular land elements 56b formed along the edge of the opening 51 in the prior-art technique into the obliquely elongated land elements 56c in this way, the number of acute-angled corners can be reduced. In addition, since the triangular land elements 56b are integrated with the adjacent rhombic land elements 56a to form obliquely elongated land elements 56c which have a larger area, the amount of solder applied to the lands close to the edge of the opening 51 can be fixed. In addition, since the obliquely elongated land elements 56c and the rhombic land elements 56a are constituted by one copper-foil coating 54 divided by a resist, it is possible to avoid a problem that, if a plurality of land elements are made from a plurality of copper-foil coatings, the outer peripheries of the copper-foil coatings are easy to peel off when heated for soldering.

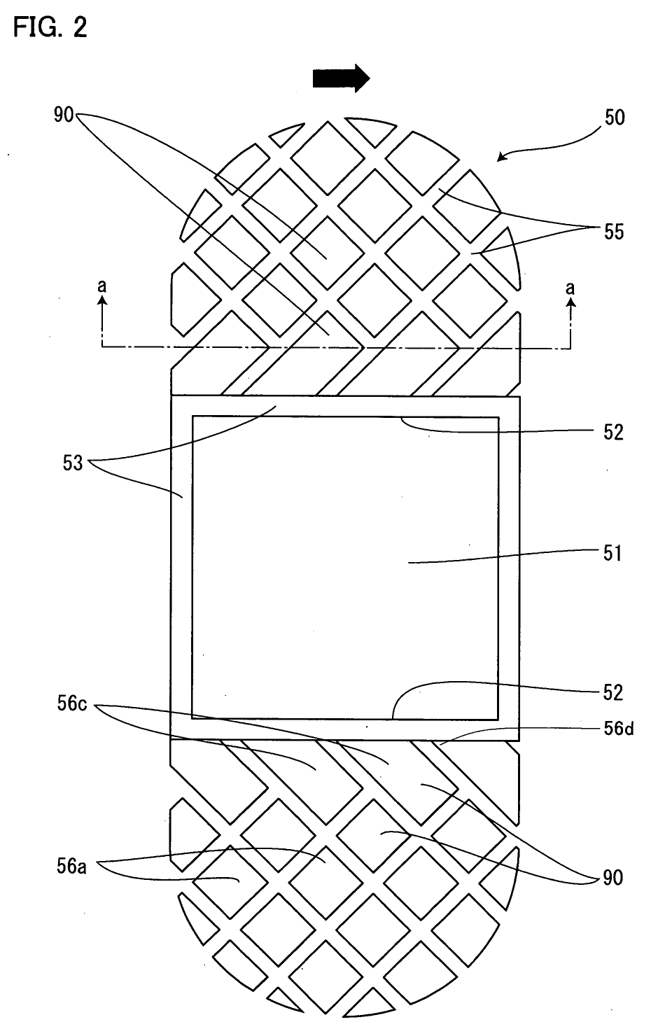

FIG. 2 shows the grounding lands 56 of the printed circuit board 50 comprising a plurality of obliquely elongated land elements 56c and a plurality of rhombic land elements 56a shown in FIG. 1, after the printed circuit board 50 is subject to flow soldering. The arrow in this drawing indicates the direction of movement of the printed circuit board 50 with respect to molten solder. The obliquely elongated land elements 56c on the printed circuit board 50 extend outward along the direction indicated by the arrow, so that each obliquely elongated land element 56c comes into contact with molten solder, first at the end thereof away from the opening 51 and last at the end thereof close to the opening 51. Thus, the amount of the solder on each obliquely elongated land element 56c is prevented from being reduced due to concentration of solder 90 at an acute corner 56d of the land element close to the opening 51. The copper-foil coating 54 constituting the plurality of obliquely elongated land elements 56c and the plurality of rhombic land elements 56a shown in FIG. 1 are coated with the solder 90 by flow soldering.

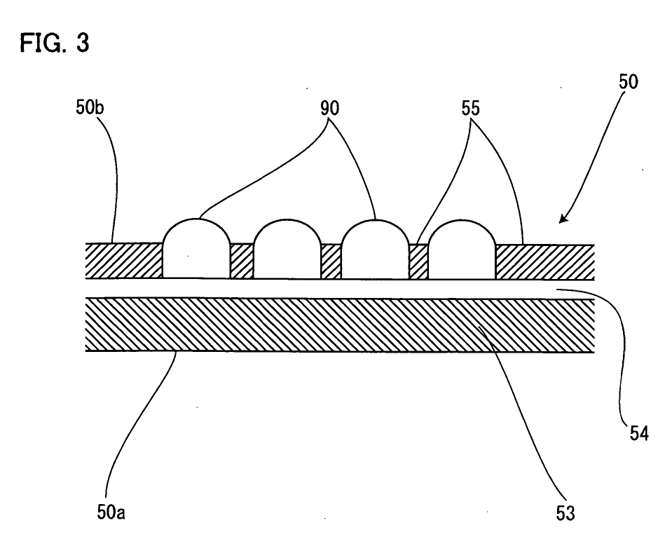

FIG. 3 is a cross-sectional view of the printed circuit board 50 shown in FIG. 2, taken along the line (a)-(a). In FIG. 3, the bottom side of the printed circuit board 50 constitutes the component mounting surface 50a, and the top side thereof constitutes a patterned surface 50b. The grounding lands 56 are formed on the patterned surface 50b, and the obliquely elongated land elements 56c constituted by the large one copper-foil coating 54 are separated from each other by the resist 55. Furthermore, as can be seen from FIG. 3, the solder 90 is applied to the parts of the copper-foil coating 54 that are not coated with the resist 55. This (a)-(a) cross-sectional view is taken along a line traversing obliquely elongated land elements 56c in parallel with an opening edge 52, and the solder 90 is applied substantially uniformly to each obliquely elongated land element 56c so as to rise above the surface of the resist 55.

### Second Embodiment

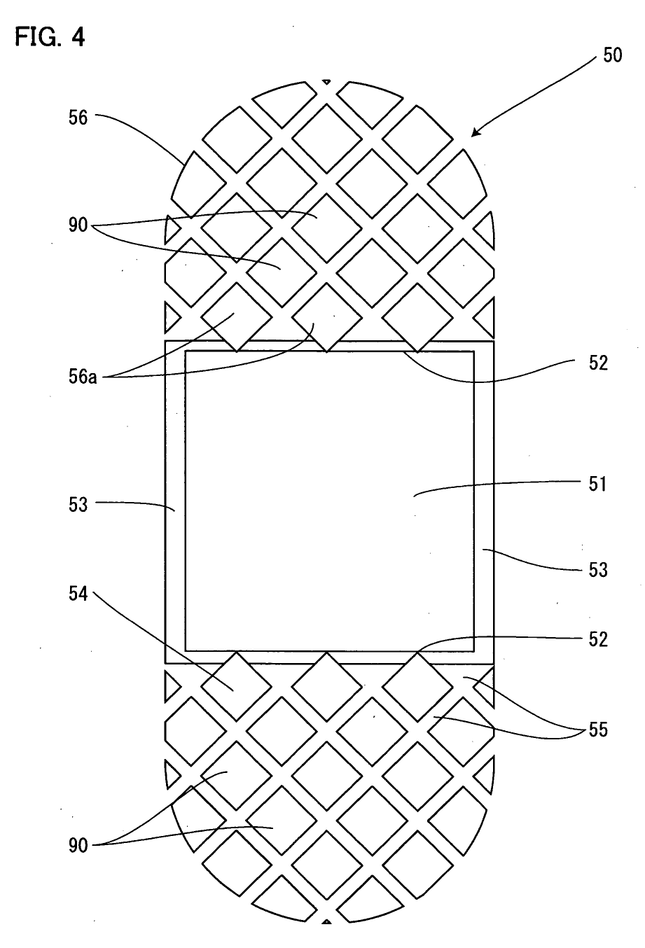

Now, a second embodiment of the present invention will be described. FIG. 4 is a diagram for illustrating a layout of grounding lands in which rhombic land elements are arranged close to an opening.

FIG. 4 shows another example of a grounding land 56, in which the triangular land elements 56b formed in the vicinity of the opening 51 according to the prior-art technique shown in FIG. 8 are changed to rhombic land elements 56a. For each of the triangular land elements 56b formed along the edge of the copper-foil coating 54 spaced apart from the opening edge 52 by approximately 0.5 mm, the copper-foil coating 54 is expanded to form an inverted-triangular land element symmetrical to the triangular land element 56b in the about—0.5-mm space in the vicinity of the opening 51, thereby forming a substantially rhombic land element. The edge of the copper-foil coating 54 on the side of the opening 51 is composed of a plurality of rhombic land elements 56a abutting on the edge of the opening 51 and thus has a saw-tooth-like shape, and the part of each tip of the saw-tooth-like edge that extends over the opening 51 can be reduced to a minimum. Thus, it is possible to reduce, to a minimum, a possibility that the copper-foil coating 54 is torn off by the cutting blade of a press die (not shown) when forming the opening 51 during fabrication of the printed circuit board 50 or a possibility that solder 90 adheres to the torn copper-foil coating, and a piece of copper foil or a piece of solder drops later and causes degradation of the product quality.

According to this configuration, the grounding land 56 has rhombic land elements 56a, constituted by the copper-foil coating 54, along the edge of the opening 51, and when applying solder to the grounding land 56, the solder is applied equally to the rhombic land elements 56a formed away from the opening edge and to the rhombic land elements 56a formed along the opening edge. Thus, the solder application can be adequately achieved.

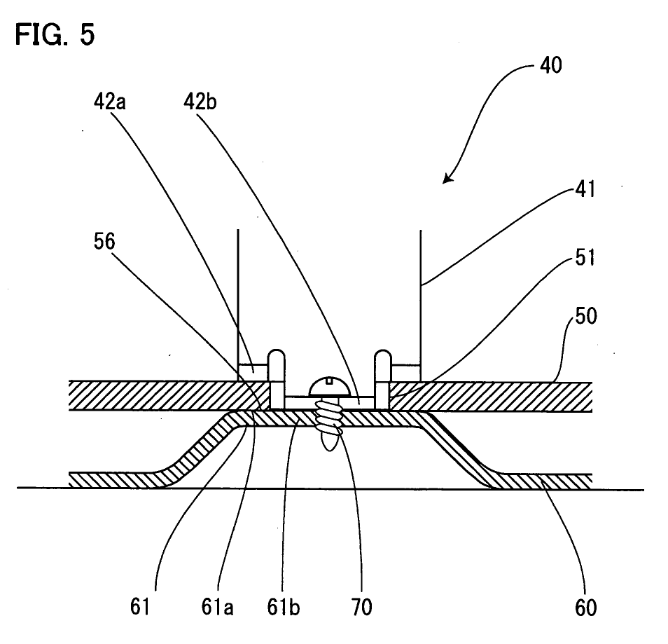

Now, with reference to FIG. 5, there will be described a cross-sectional view of the grounding land 56 on the printed circuit board 50 that is mounted on a supporting mount 61 formed on a conductive chassis 60 and fixed by the a locking leg 41 formed on a conductive frame 40.

The supporting mount 61 formed on the conductive chassis 60 has a screw hole, and a locking-leg contacting part 61b is formed surrounding the screw hole. In addition, board contacting parts 61a are formed at the opposite sides of the locking-leg contacting part 61b. The grounding lands 56 on the printed circuit board 50 are aligned with and mounted on the board contacting parts 61a, a stepped chassis contacting part 42b of the locking leg 41 on the conductive frame 40 passes through the opening 51 in the printed circuit board 50 and is in contact with the locking-leg contacting part 61b of the supporting mount 61 and screw-clamped thereto. Thus, through the flat surface of the locking-leg contacting part 61b, the conductive frame 40 can be reliably connected to the conductive chassis 60 for grounding. In addition, a stepped board pressing part 42a formed on the locking leg 41 can press the grounding lands 56 on the printed circuit board 50 from the back side thereof by the screw-clamping force. Thus, through the flat surface of the board contacting part 61a, the printed circuit board 50 can be reliably connected to the conductive chassis 60 for grounding.

As described above, according to this embodiment, in the electronic apparatus incorporating the printed circuit board having the grounding land of the present invention, the printed circuit board 50 and the conductive frame 60 can be brought into contact with and firmly pressed against the conductive chassis 60 by simply screw-clamping the locking leg 41 to the conductive chassis 60. Besides, the prior-art technique has a problem with product quality that, when a press die (not shown) is used to shape the printed circuit board 50 or to form the opening 51 that serves as a component insertion hole, the copper-foil coating 54 may be torn off by the cutting blade of the die if the opening 51 is relatively large or that solder 90 may adhere to a protruding part of the torn copper-foil coating, and a piece of copper foil or a piece of solder may drop later. However, according to this embodiment, the copper-foil coating 54 is slightly spaced apart from the opening edge 52 in the printed circuit board 50, and the grounding land 56 is constituted by one copper-foil coating 54 divided by a substantially lattice-shaped resist 55. Thus, the possibility can be avoided that the copper-foil coating 54 easily peels off by heat during soldering if the periphery of the copper-foil coating 54 is not coated with the resist 55, and an edge or corner thereof is exposed.

In addition, the prior-art technique has a problem that a plurality of land elements 56a, which would otherwise be rhombic land elements 56a, are triangular land elements 56b because of the presence of the opening 51, and thus, those land elements 56a have a reduced area. In order to solve this problem, the triangular land elements 56b in the vicinity of the opening 51 are integrated with their respective obliquely adjacent rhombic land elements 56a to form obliquely elongated land elements 56c, thereby providing adequately large land elements and ensuring that an adequate amount of solder is applied to each land element. Furthermore, there is a problem that each of the obliquely elongated land elements 56c has an acute-angled narrow corner on the side close to the opening 51, and the amount of solder applied to the narrow corner tends to decrease. In order to solve this problem, the obliquely elongated land elements are disposed in such a manner that, during flow soldering, as the printed circuit board 50 moves, the molten solder 90 is drawn toward the opening 51 by the action of the interfacial tension between the molten solder and the copper-foil coating 54, and the height of the solder applied to the narrow corner of the obliquely elongated land element 56c increases, thereby adjusting the heights of solder on the rhombic land elements 56a, the obliquely elongated land elements 56c and the land elements located along the periphery of the grounding land 56, thereby ensuring the contact between the grounding land 56 on the printed circuit board 50 and the conductive chassis 60. Thus, according to the grounding method, the grounding land 56 is in direct contact with the conductive chassis 60 and thus is electrically connected thereto with reliability. In addition, the printed circuit board 50, which is screw-clamped to the conductive chassis 60, is pressed against the conductive chassis 60 by the locking leg 41 of the conductive frame 40, and thus, the resiliency of the stepped parts 42 of the locking leg 41 prevents loosening of the screw due to a creep of the solder 90.

Alternatively, in order to solve the problem that a plurality of land elements 56a, which would otherwise be rhombic land elements 56a, are triangular land elements 56b because of the presence of the opening 51, and thus, those land elements 56a have a reduced area, the copper-foil coating 54 is expanded to form inverted-triangular land elements symmetrical to the triangular land elements 56b in the about 5 mm space that is not coated with copper foil in the vicinity of the opening 51, thereby forming rhombic land elements 56a. Thus, the grounding land 56 has a plurality of rhombic land elements 56a instead of the triangular land elements 56b, so that the amount of solder on the land elements can be made uniform and constant, and the grounding land 56 on the printed circuit board 50 can be reliably brought into contact with the conductive chassis 60. In addition, since the grounding land 56 is in direct contact with the conductive chassis 60, the grounding land 56 can be electrically connected to the conductive chassis 60 with reliability. Furthermore, the edge of the copper-foil coating 54 on the side of the opening 51 is composed of a plurality of rhombic land elements 56a abutting on the edge of the opening 51 and thus has a saw-tooth-like shape, and the part of each tip of the saw-tooth-like edge that extends over the opening 51 can be reduced to a minimum. Thus, it is possible to reduce, to a minimum, a possibility that the copper-foil coating 54 is torn off by the cutting blade of a press die (not shown) when forming the opening 51 during fabrication of the printed circuit board 50, or a possibility that solder 90 adheres to the torn copper-foil coating, and a piece of copper foil or a piece of solder drops later and causes degradation of the product quality.

While embodiments of the present invention have been described in detail, the present invention is not limited thereto and can be modified in various ways without departing from the spirit of the present invention. For example, the opening 51 in the printed circuit board 50 may not be rectangular and can have any shape as far as the locking leg 41 can pass therethrough. Furthermore, the resist 55, which serves to divide the grounding land 56 into plural land elements, may be applied by silk-screen printing, which is typically used for printing a symbol or character on the printed circuit board 50. Furthermore, the shape of the grounding land 56 is not limited to that shown in the embodiments described above, but can be appropriately modified taking into account the ease of fabrication of the printed circuit board 50 or the ease of assembly of the electronic apparatus (not shown).

1. An electronic apparatus incorporating a printed circuit board having a grounding land, an electronic component being mounted on the printed circuit board, wherein an opening is formed through the printed circuit board, a copper-foil coating for grounding is formed on the printed circuit board at a predetermined distance from an edge of the opening, the copper-foil coating is divided by a lattice-shaped resist into a plurality of land elements, and the plurality of land elements are formed in such a manner that land elements close to the edge of the opening have an area equal to or larger than the area of land elements away from the edge of the opening.

2. An electronic apparatus incorporating a printed circuit board having a grounding land, comprising: a conductive frame for holding an electronic device or component incorporated therein; a printed circuit board on which the electronic component is mounted; and a conductive chassis to which the conductive frame and the printed circuit board are fixed by screw clamping to provide electrical grounding, the conductive chassis having a raised supporting mount which supports the printed circuit board and serves as a contact surface for grounding, the conductive frame having a locking leg having stepped parts which are different in height by approximately the thickness of the printed circuit board, one of the stepped parts serving to pressing the printed circuit board against the supporting mount, and the other of the stepped parts passing through an opening formed in the printed circuit board and being screw-clamped to the supporting mount, wherein a copper-foil coating for grounding is formed on the printed circuit board at a predetermined distance from an edge of the opening, the copper-foil coating is divided by a lattice-shaped resist into a plurality of rhombic land elements, each of which has a substantially rhombic shape, and a plurality of obliquely elongated land elements are disposed along the edge of the opening.

3. The electronic apparatus incorporating a printed circuit board having a grounding land according to claim 1, wherein the plurality of obliquely elongated land elements abutting on the edge of the opening are disposed so as to extend outward from the opening in a direction in which the printed circuit board moves while being in contact with molten solder during flow soldering.

4. The electronic apparatus incorporating a printed circuit board having a grounding land according to claim 1, wherein the copper-foil coating for grounding is formed on the printed circuit board at a predetermined distance from the edge of the opening, the copper-foil coating is divided by a lattice-shaped resist into a plurality of substantially rhombic land elements, and the copper-foil coating is expanded toward the edge of the opening to form a plurality of rhombic land elements along the edge of the opening.

5. The electronic apparatus incorporating a printed circuit board having a grounding land according to claim 2, wherein the plurality of obliquely elongated land elements abutting on the edge of the opening are disposed so as to extend outward from the opening in a direction in which the printed circuit board moves while being in contact with molten solder during flow soldering.
